(19) United States
(12) Patent Application Publication
(10) Pub. No.: US 2002/0102796 A1
(43) Pub. Date: Aug. 1, 2002

(54) Method for forming dual gate electrode for semiconductor device

(76) Inventors: Kwang-pyo Lee, Gyunggi-do (KR); Sang-soo Lee, Gyunggi-do (KR)

Correspondence Address: MARSHALL, GERSTEIN & BORUN, 6300 SEARS TOWER, 233 SOUTH WACKER, CHICAGO, IL, 60606-6357, US

(21) Appl. No.: 09/888,783

(22) Filed: Jun. 25, 2001

(30) Foreign Application Priority Data
Jun. 29, 2000 (KR) 2000-36637

(51) Int. Cl. H01L 21/336

(52) U.S. Cl. 438/283

(57) ABSTRACT

A method for forming a dual-gate for a semiconductor device includes an N-counter implantation process that implants an N-type impurity ion like phosphorous through an ultra low energy implanter to provide an in-situ boron doped polysilicon layer with a stable characteristic. The method includes: forming a gate insulation layer on a semiconductor substrate; depositing a P-type doped polysilicon layer on an upper part of the gate insulation layer; forming a photoresist film on one region of the doped polysilicon layer thereby leaving an adjacent region of the P-type polysilicon layer open for a MOS transistor region; forming N-type doped polysilicon layer by performing an N-counter implantation process at the open region of the NMOS transistor; depositing a tungsten nitride layer and a tungsten layer sequentially on the upper part of the N- and P-type doped polysilicon layers after removing the photoresist film; and forming a gate electrode of the PMOS transistor constructed by the tungsten layer, the tungsten nitride layer and the P-type doped polysilicon layer and a gate electrode of the NMOS transistor constructed by the tungsten layer, the tungsten nitride layer and the N-type doped polysilicon layer by performing the photo and etch processes.

### BACKGROUND

1. Technical Field

The present invention relates to a method for forming a dual-gate electrode, and, in particular, to a method for forming a dual-gate for a semiconductor device. More specifically, the present invention relates to a method wherein an N-counter doping process is performed for implanting an N-type impurity like phosphorous through an ultra low energy implanter to provide an in-situ boron doped polysilicon layer with a stable characteristic.

2. Description of the Background Art

When the length of a PMOS channel is less than 0.3 μm, several problems arise in that the threshold voltage is increased and a leakage characteristic is deteriorated, so that a PMOS transistor with a buried channel cannot be used. In order to solve these problems, a dual gate capable of reducing a device and operating at a low voltage has been used.

Processes for forming a conventional dual gate are as follows: an N-type doped polysilicon layer is formed by implanting an N-type impurity like phosphorous on an undoped polysilicon layer at the region of an NMOS transistor and a P-type doped polysilicon layer is formed by implanting a P-type impurity like boron on an undoped polysilicon layer in the region of a PMOS transistor.

When the region between devices and an active region are diminished, the height of the gate electrode must be raised relatively. However, since the N-type and P-type doped polysilicon layers are formed by implanting impurities on undoped polysilicon layers, there is a limitation in the height of the gate electrode for securing a desired conductance, so that the thickness of the undoped polysilicon layer must also be less than 1000 Å. However, when an impurity is implanted on the thin undoped polysilicon layer, since a thermal stability of the thin undoped polysilicon layer is weak, the boron is diffused to the upper WSix layer or TiSix layer. As a result, there are problems in that an impurity depletion of the gate electrode and a penetration phenomenon of boron to the semiconductor substrate are generated, thereby lowering the threshold voltage. Also, there is a problem in that it is difficult to form the P-type doped polysilicon layer being required the P-type impurity implantation with a high concentration.

In order to solve these problems, the application of the in-situ boron doped polysilicon layer, which is deposited the undoped polysilicon layer and at the same time implanted the P-type impurity ion like boron is introduced.

However, in the above case, since the entire undoped ploy silicon layer of the gate electrode becomes the P-type doped polysilicon layer, a problem occurs at the region of the NMOS transistor in the DRAM chip. In the case of a PMOS transistor, since the in-situ boron-doped polysilicon layer is used, it has a similar characteristic to the in-situ updoped polysilicon layer being used. The impurity depletion of the gate electrode and the boron penetration phenomenon can also be prevented. Consequently, the characteristic of the PMOS transistor can be enhanced significantly.

However, in a case of the NMOS transistor occupying the majority of the region of the device, the P-type doped polysilicon layer must be changed into the N-type doped polysilicon layer. In order to form the N-type polysilicon layer, although a POCl₃ implantation process has been used, it does not nearly used at present, it is impossible to use due to a high thermal requirement and difficulty in implantation concentration control.

Due to the above problems, the in-situ boron doped polysilicon layer has not been used until now.

In a high cost device, hereafter, since a low thermal requirement is used, the application of POCl₃ implantation process itself is impossible.

Therefore, in order to realize a surface channel CMOS transistor with a stable characteristic using an in-situ boron-doped polysilicon layer, there is a need for an N-counter implantation process for forming an N-type doped polysilicon layer of a gate electrode in the region of the NMOS transistor.

### SUMMARY OF THE DISCLOSURE

A method for forming a dual gate electrode for a semiconductor device is disclosed which comprises an N-counter implantation process that implants an N-type impurity ion like phosphorous through an ultra low energy implanter to the region of the NMOS transistor region so in-situ boron-doped polysilicon layer can be used with a stable characteristic in a surface channel CMOS fabrication method.

The disclosed method comprises: forming a gate insulation layer on a semiconductor substrate; depositing a P-type doped polysilicon layer on an upper part of the gate insulation layer; forming a photoresist film on one region of the P-type doped polysilicon layer thereby leaving an adjacent MOS transistor region of the P-type polysilicon layer open; forming N-type doped polysilicon layer by performing an N-counter implantation process at the region of the opened NMOS transistor; depositing a tungsten nitride layer and a tungsten layer sequentially on the upper part of the N- and P-type doped polysilicon layers after removing the photoresist film; and forming a gate electrode of the PMOS transistor constructed by the tungsten layer, the tungsten nitride layer and the P-type doped polysilicon layer and a gate electrode of the NMOS transistor constructed by the tungsten layer, the tungsten nitride layer and the N-type doped polysilicon layer by performing the photo and etch processes.

### BRIEF DESCRIPTION OF THE DRAWINGS

The present invention can be understood with reference to the accompanying drawings, which are given only by way of illustration and thus are not limitative of the present invention, wherein:

FIGS. 1 to 4 are cross-sectional views illustrating a method for forming a dual gate electrode for a semiconductor device in accordance with the present invention.

### DETAILED DESCRIPTION OF THE PRESENTLY PREFERRED EMBODIMENTS

A method for forming a dual gate electrode for a semiconductor device will now be described with reference to the accompanying drawings.

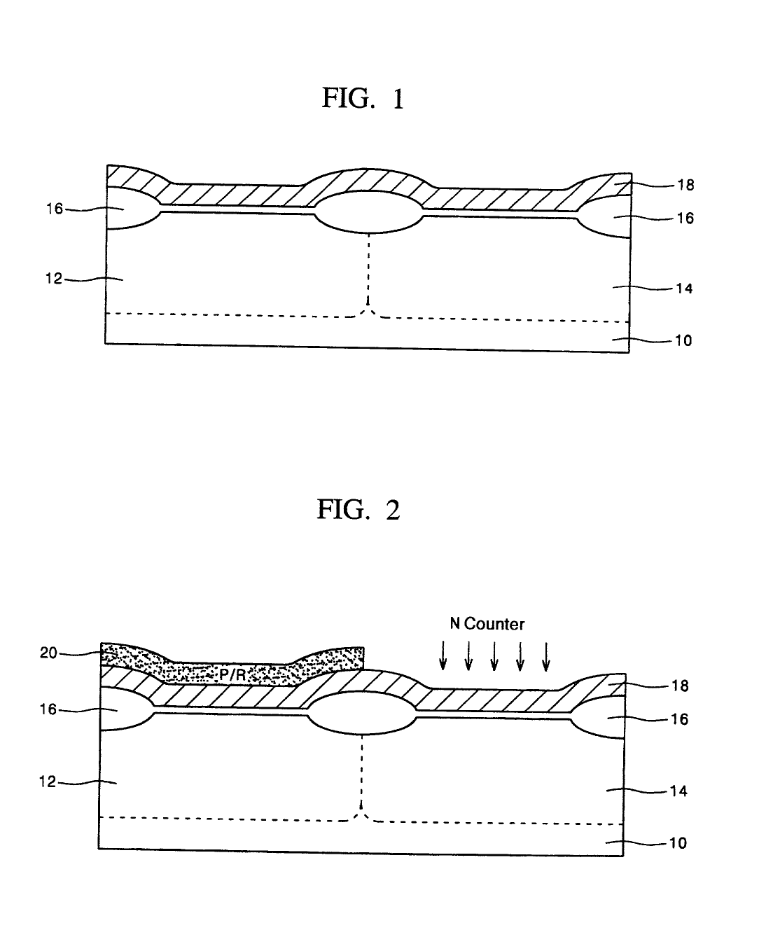

FIGS. 1 to 4 are cross-sectional views illustrating a method for forming a dual gate electrode for a semiconductor device.

As shown in FIG. 1, an N-well 12 is formed by implanting an N-type impurity like phosphorous into a PMOS transistor region of a semiconductor substrate 10 and a P-well 14 is formed by implanting a P-type impurity like boron into an NMOS transistor region of the semiconductor substrate 10.

After performing a well anneal and a device isolation processes, a gate insulation layer 16 is formed.

When forming the gate insulation layer 16, an oxide layer with a thickness ranging from about 30 to about 50 Å is formed by a wet oxidation method at the temperature of about 800° C. by using hydrogen and oxygen gases. At this time, one or more among NH₃, NO and N₂O may be used simultaneously to form an oxinitride layer.

Thereafter, a P-type doped polysilicon layer 18 with a thickness ranging from about 500 to about 1500 Å is deposited on an upper portion of the gate insulation layer 16.

The P-type doped polysilicon layer 18 is formed by using a chemical vapor deposition (CVD) method and so an in-situ born-doped polysilicon layer is formed. SiH₄, Si₂H₆ or SiH₂Cl₂ are used as silicon sources and B₂H₆ and BCl₃ are used as boron sources. The process is performed in condition that the concentration of boron is above 1×10²⁰ atoms/cm³ and the temperature ranging from about 500 to about 700° C. and the pressure is maintained at less than 200 Torr.

As above-formed, an impurity depletion of the gate electrode, a penetration of boron to the semiconductor substrate and a diffusion of boron to the side of the NMOS gate are prevented by the stable boron within the P-type doped polysilicon layer 18.

And, since the boron also plays a role of fixing phosphorous within an N-type doped polysilicon layer 18′ formed by the next N-counter implanting process using an N-type impurity, an impurity depletion of the gate electrode and a lateral diffusion to the PMOS gate by the diffusion of phosphorous can be prevented.

When depositing the P-type doped polysilicon layer 18, at the beginning of the deposition process, a layer containing together nitrogen and boron, with a thickness ranging from about 50 to about 100 Å, is formed by using gas, that is, NH₃ gas containing nitrogen at about 750° C. and under 1 Torr, so that the diffusion of dopant like boron and phosphorous can be prevented.

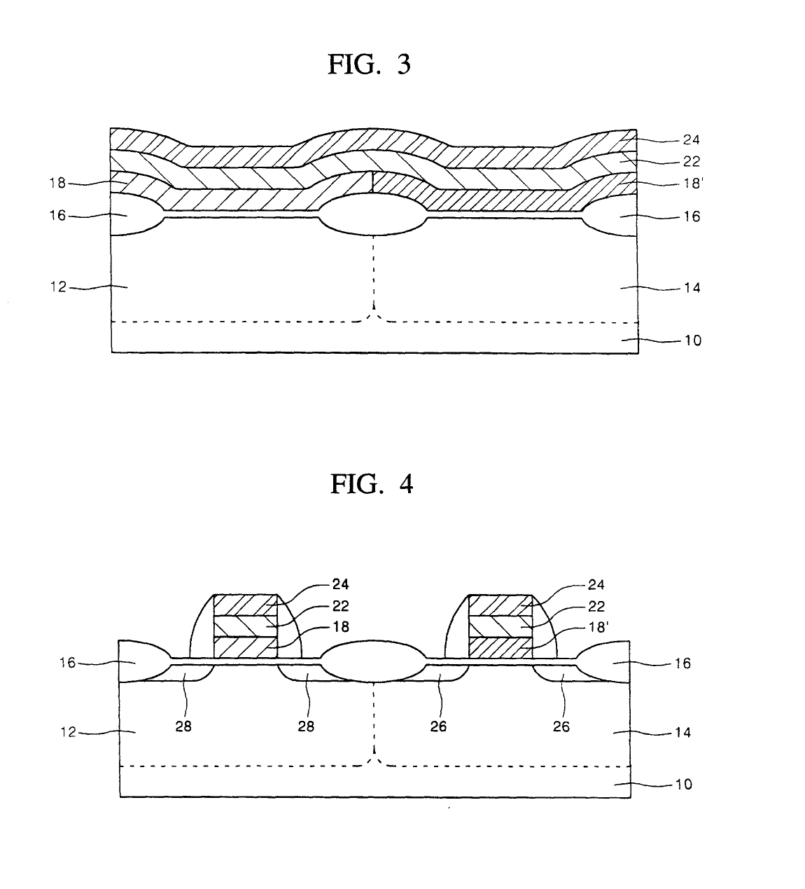

As shown in FIG. 2, after forming a photoresist film 20 for opening the P-type doped polysilicon 18 on the NMOS transistor region, the N-type doped polysilicon layer 18′ (see FIG. 3) is formed to the NMOS transistor region by performing an N counter ion implantation process. At this time, a P-well mask instead of the photoresist film may be used.

The N-counter implanting process uses phosphorous or arsenic as N-type impurity sources and the impurity is implanted at an energy of less than 20 KeV and at a concentration of about 1.0×10¹⁵˜1.0×10¹⁷/cm².

Thereafter, as shown in FIG. 3, after removing the photoresist film 20, a tungsten nitride layer 22 with about the thickness ranging from about 50 to about 100 Å and a tungsten layer 24 with the thickness ranging from about 500 to about 1000 Å are sequentially deposited to upper parts of the N-type and P-type doped silicon layer.

Thereafter, as shown in FIG. 4, a gate electrode of the PMOS transistor constructed by the tungsten layer 24, the tungsten nitride layer 22 and the P-type doped polysilicon layer 18, and a gate electrode of the NMOS transistor constructed by the tungsten layer 24, the tungsten nitride layer 22 and the N-type doped polysilicon layer 18′ are formed by performing the photo and etch processes.

Thereafter, a PMOS source/drain 28 is formed at the region of the PMOS transistor by implanting a P-type impurity like boron by using an implant mask, and an NMOS source/drain 26 is formed at the region of the NMOS transistor by implanting an N-type impurity like phosphorous by using an implant mask.

As described above, the P-type doped polysilicon layer is formed by using the in-situ boron doped polysilicon layer, so that the impurity depletion of the gate electrode can be prevented and the gate electrode with the low leakage current and the high saturation current at a low voltage can be formed.

The N-type doped polysilicon layer is also formed through the N-counter ion implantation process and so the gate electrode of the NMOS transistor can be formed that is capable of easily controlling the thermal requirement and the impurity implantation concentration.

The dual gate electrode having the above characteristics can use the real device, so that the characteristics of DRAM (Dynamic Random Access Memory), SRAM (Static Random Access Memory), Flash memory and MML (Merged Memory and Logic) devices are enhanced and the number of net die is increased.

According to the present invention, there are also advantages that the yield can be increased according to the increase of process margin and the reliability can be enhanced.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the meets and bounds of the claims, or equivalences of such meets and bounds are therefore intended to be embraced by the appended claims.

What is claimed is:

1. A method for forming a dual gate for a semiconductor device comprising:
forming a gate insulation layer on a semiconductor substrate;
depositing a P-type doped polysilicon layer on an upper part of the gate insulation layer, the P-type doped polysilicon layer having a first region and a second MOS transistor region;
forming a photoresist film on the first region of the P-type doped polysilicon layer for opening the P-type polysilicon layer on the second MOS transistor region;
forming N-type doped polysilicon layer by performing an N-counter implantation process on the second NMOS transistor region;
removing the photoresist film;
depositing a tungsten nitride layer and a tungsten layer sequentially on the N-and P-type doped polysilicon layers; and
forming a gate electrode of a PMOS transistor constructed by the tungsten layer, the tungsten nitride layer and the P-type doped polysilicon layer and a gate electrode of a NMOS transistor constructed by the tungsten layer, the tungsten nitride layer and the N-type doped polysilicon layer by performing photo and etch processes.

2. The method of claim 1, wherein the gate insulation layer is formed by using an oxygen and hydrogen gases through a wet etch and has a thickness ranging from about 30 to about 50 Å.

3. The method of claim 1, wherein the P-type doped polysilicon layer is formed by a chemical vapor deposition thereby forming an in-situ boron doped polysilicon layer with a thickness ranging from about 500 to about 1000 Å.

4. The method of claim 3, wherein during the chemical vapor deposition of the in-situ boron doped polysilicon layer, at least one silicon source selected from the group consisting of SiH₄, Si₂H₆ and SiH₂Cl₂ is used and at least one boron source selected from the group consisting of B₂H₆ and BCl₃ is used as boron sources.

5. The method of claim 3, wherein during the chemical vapor deposition of the in-situ boron doped polysilicon layer, at the beginning of the deposition process, a layer containing together nitrogen and boron having a thickness ranging from about 50 to about 100 Å is formed by using NH₃ gas containing nitrogen at a temperature of about 750° C. and a pressure of less than 1 Torr in order to prevent the diffusion of boron and phosphorus.

6. The method of claim 3, during the chemical vapor deposition of the in-situ boron doped polysilicon layer, a concentration of boron is employed that is greater than 1×10²⁰ atoms/cm³ and the deposition is carried out at a temperature ranging from about 500 to about 700° C. and at a pressure of less than 200 Torr.

7. The method of claim 1, wherein during the N-counter implantation process, phosphorous or arsenic is used as N-type impurity sources at an energy of less than about 20 KeV and at a concentration ranging from about 1.0×10¹⁵ to about 1.0×10¹⁷/cm².
